(19) United States
(12) Patent Application Publication
(10) Pub. No.: US 2015/0044467 A1
(43) Pub. Date: Feb. 12, 2015

(54) METHOD OF GROWING INGOT AND INGOT

(71) Applicants: Hwajin Jo, Gyeongsangbuk-do (KR); Sanghee Kim, Seoul (KR); Youngho Jung, Busan (KR); Namseok Kim, Seoul (KR)

(72) Inventors: Hwajin Jo, Gyeongsangbuk-do (KR); Sanghee Kim, Seoul (KR); Youngho Jung, Busan (KR); Namseok Kim, Seoul (KR)

(21) Appl. No.: 13/821,005

(22) PCT Filed: Nov. 30, 2011
(86) PCT No.: PCT/KR12/10332

§ 371 Date: Mar. 5, 2013

(30) Foreign Application Priority Data
Apr. 23, 2012 (KR) 10-2012-0041987

(51) Int. Cl. C30B 15/36; C30B 15/04; C30B 29/06; C30B 15/14

(52) U.S. Cl. CPC C30B 15/36; C30B 15/14; C30B 15/04; C30B 29/06
USPC 428/399; 117/13; 117/21

(57) ABSTRACT

Provided is a method of growing an ingot. The method of growing the ingot includes melting a silicon to prepare a silicon melt solution, preparing a seed crystal having a crystal orientation [110], growing a neck part from the seed crystal, and growing an ingot having the crystal orientation [110] from the neck part. The neck part has a diameter of about 4 mm to about 8 mm.

### CROSS-REFERENCE TO RELATED APPLICATIONS

The present application is a national phase application of P.C.T. application PCT/KR2012/010332 filed Nov. 30, 2011, which claims the priority benefit of Korean patent application 10-2012-0041987 filed Apr. 23, 2012, the disclosures of which are incorporated herein by reference.

### BACKGROUND OF THE INVENTION

1. Field of the Invention

The present disclosure relates to a method of growing an ingot and an ingot.

2. Description of the Related Art

Generally, a process of manufacturing a wafer for manufacturing a semiconductor device may include a slicing process for slicing a silicon monocrystalline ingot, an edge grinding process for rounding an edge of the sliced wafer, a lapping process for planarizing a rough surface of the wafer due to the slicing process, a cleaning process for removing particles and all sorts of contaminants which are attached to a surface of the wafer during the edge grinding or lapping process, a surface polishing process for securing a shape and surface suitable for post processes, and an edge polishing process with respect to the edge of the wafer.

Silicon monocrystalline ingots may be grown through a czochralski (CZ) method or a floating zone (FZ) method. The CZ method is commonly used for growing silicon monocrystalline ingots because large-diameter single monocrystalline ingots are capable of being manufactured through the CZ method, and also the CZ method is relatively inexpensive method.

The CZ method may be performed by immersing a seed crystal in silicon melt solution and then lifting the seed crystal at a low speed.

However, products having new crystal orientations are required to overcome limitation of existing semiconductor devices. For example, a product having a crystal orientation [110] is expected as a next generation product. However, when compared to an ingot having crystal orientation [100], an ingot having the crystal orientation [110] have low crystalline because a dislocation is propagated in a crystal growth direction, and also, it is difficult to control the dislocation.

### SUMMARY OF THE CLAIMED INVENTION

### Technical Problem

Embodiments provide a high-quality wafer having a crystal orientation [100].

### Technical Solution

In one embodiment, a method of growing an ingot includes: melting a silicon to prepare a silicon melt solution; preparing a seed crystal having a crystal orientation [110]; growing a neck part from the seed crystal; and growing an ingot having the crystal orientation [110] from the neck part, wherein the neck part has a diameter of about 4 mm to about 8 mm.

The details of one or more embodiments are set forth in the accompanying drawings and the description below. Other features will be apparent from the description and drawings, and from the claims.

### Advantageous Effect

According to the method of growing the ingot, the high-quality ingot having the crystal orientation [110] may be grown. That is, the wafer having the new crystal orientation which is capable of overcoming the limitations of the semiconductor device according to the related art may be manufactured. That is, the wafer having the improved device efficiency may be manufactured using the ingot having the crystal orientation [110].

Particularly, the boron concentration of the seed crystal may correspond to the doping concentration of the silicon melt solution. Therefore, an occurrence of the misfit due to a concentration difference between the silicon melt solution and the seed crystal may be controlled. The misfit dislocation represents a dislocation occurring within the seed crystal when the seed crystal contacts the silicon melt solution due to a constant different therebetween in a case where the doping concentration of the silicon melt solution is different from that of the seed crystal. In the embodiment, the misfit dislocation may be controlled to grow the monocrystalline having high quality

Also, since the neck part grown by the method of growing the ingot according to the embodiment has a diameter greater than that of the neck part according to the related art, the neck part may support the large-size high-weight ingot. That is, the process failure may be prevented, and the process yield may be improved.

### BRIEF DESCRIPTION OF THE DRAWINGS

FIG. 1 is a flowchart illustrating a method of growing an ingot according to an embodiment.

FIG. 2 is a perspective view of an ingot manufactured through the method of growing the ingot according to an embodiment.

FIG. 3 is a cross-sectional view of an apparatus for manufacturing an ingot which is used for a method of growing an ingot according to an embodiment.

FIG. 4 is a graph illustrating experimentation data with respect to a dislocation length to a neck part diameter in a method of growing an ingot according to an embodiment.

### DETAILED DESCRIPTION

In the drawings, the thickness or size of each layer (film), each region, each pattern, or each structure is modified for convenience in description and clarity. Thus, the size of each element does not entirely reflect an actual size.

Example embodiments will now be described more fully hereinafter with reference to the accompanying drawings.

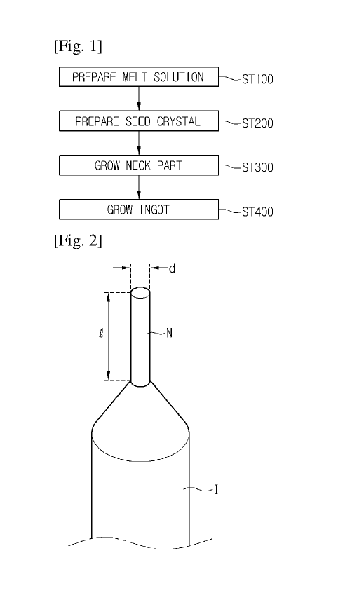

Referring to FIGS. 1 and 2, a method of growing an ingot according to an embodiment and an ingot manufactured by the method will be described below in detail. FIG. 1 is a flowchart illustrating a method of growing an ingot according to an embodiment. FIG. 2 is a perspective view of an ingot manufactured through the method of growing the ingot according to an embodiment.

A method of growing an ingot according to an embodiment includes preparing a melt solution (ST100), preparing a seed crystal (ST200), growing a neck part (ST300), and growing an ingot (ST400).

In the preparing of the melt solution (ST100), a silicon melt solution may be prepared in a quartz crucible installed within a chamber. That is, in the preparing of the melt solution (S100), silicon may be melted to prepare a silicon melt solution. The silicon melt solution may have a doping concentration of about 8.5×1018 atoms/cm3 to about 1.7×1019 atoms/cm3. Particularly, the silicon melt solution may be doped with boron. Here, the boron may have a concentration of about 8.5×1018 atoms/cm3 to about 1.7×1019 atoms/cm3. In the boron doping concentration, boron may be heavily doped for determining an EPI-substrate, but not a general specific resistance band.

Particularly, in the preparing of the melt solution (ST100), a magnetic field may be applied. Particularly, the magnetic field may be applied into a lower side from a surface of the silicon melt solution. More particularly, if a level of the surface of the silicon melt solution is zero, the maximum magnetic field may be applied into a position corresponding to a level of about −100 mm from the zero. The magnetic field may have intensity of about 1,500 G to about 3,500 G. As a result, a temperature deviation of the silicon melt solution may be reduced. Thus, the dislocation may be controlled.

In the preparing of the seed crystal (ST200), a seed crystal having a crystal orientation [110] may be prepared. Thus, an ingot having the crystal orientation [110] may be grown from the seed crystal.

The seed crystal may have a boron concentration of about 8.5×1018 atoms/cm3 to about 1.7×1019 atoms/cm3. That is, the boron concentration of the seed crystal may correspond to the doping concentration of the silicon melt solution. Therefore, an occurrence of a misfit due to a concentration difference between the silicon melt solution and the seed crystal may be controlled. The misfit dislocation represents a dislocation occurring within the seed crystal when the seed crystal contacts the silicon melt solution due to a constant different therebetween in a case where the doping concentration of the silicon melt solution is different from that of the seed crystal. In the current embodiment, the misfit dislocation may be controlled to grow a monocrystalline having high quality.

Next, in the growing of the neck part (ST300), the neck part may be grown from the seed crystal. That is, the neck part N having a thin and long shape may be grown from the seed crystal.

In the growing of the neck part (ST300), the neck part may have a growth rate of about 3.0 mm/min to about 3.2 mm/min. Thus, the neck part may be quickly grown than a dislocation velocity to control the dislocation.

If the neck part has a growth rate of about 2 mm/min or less, the neck part may be increased in diameter. Thus, it may be more difficult to control the dislocation of the neck part in a [110] crystal. On the other hand, if the neck part has a growth rate of about 4 mm/min or more, the neck part may be decreased in diameter. Thus, the neck part may be vulnerable to a weight. Thus, the neck part may have a growth rate of about 3 mm/min to about 3.2 mm/min.

Referring to FIG. 2, the neck part N may have a length t of about 400 mm or more. Also, the neck part N may have a diameter d of about 4 mm to about 8 mm. Since the neck part N has a diameter greater than that of a neck part according to a related art, the neck part N may support a large-size high-weight ingot. That is, process failure may be prevented, and process yield may be improved.

In detail, if the neck part has a diameter less than about 4 mm, the neck part may not endure a weight of a large scale ingot having a diameter of about 300 mm or more during the growth of the ingot. Thus, the neck part may be broken to cause loss. Also, if the neck part has a diameter greater than about 8 mm, it may be difficult to control the dislocation of the neck part.

A reason in which the neck part has a diameter of about 4 mm to about 8 mm and a length of about 400 mm or more will be described with reference to following experimentation results.

Table below illustrates results obtained by arranging a dislocation length according to a diameter of the neck part. FIG. 4 illustrates the experimentation data of Table of FIG. 4 as a graph.

TABLE 1

| | Neck | Dislocation |
|---|---|---|
| Orientation | Diameter | length |
| [110] | 2.9 | 175 |
| | 2.9 | 165 |
| | 3.0 | 220 |
| | 3.0 | 230 |
| | 3.0 | 230 |
| | 5.92 | 270 |
| | 6.81 | 350 |
| | 6.24 | 280 |
| | 5.98 | 300 |
| | 6.48 | 390 |
| | 6.82 | 400 |
| | 5.1 | 320 |
| | 5.98 | 300 |
| | 5.92 | 270 |

Referring to Table 1 and FIG. 4, when the neck part has a length less than about 400 mm, the dislocation length is short. Thus, although productivity is improved, it may be difficult to control the dislocation in the [110] crystal. As a result, products may be deteriorated in quality.

Thus, it may be necessary that the neck part has a length of about 400 mm or more so that the neck part has a diameter of about 4 mm to about 8 mm to more easily control the dislocation.

In the growing of the ingot (ST400), an ingot I may be grown from the neck part N. That is, an ingot having a crystal orientation [110] may be grown. That is, a wafer having a new crystal orientation which is capable of overcoming the limitations of the semiconductor device according to the related art may be manufactured. That is, a wafer having improved device efficiency may be manufactured using the ingot having the crystal orientation [110].

In the growing of the ingot (ST400), the ingot may have a lifting speed of about 0.9 mm/min or more. Thus, a cooling rate of the crystalline may be increased by a growth apparatus including a cooler to improve heat resistance. Also, the dislocation may be multiplied to confirm whether a polycrystalline exists with a naked eye, thereby securing the monocrystalline.

The growing of the ingot (ST400) may include a shouldering formation process for expanding a diameter of the neck part N to a target diameter and a body growth process for growing the silicon monocrystalline ingot while maintaining the target diameter.

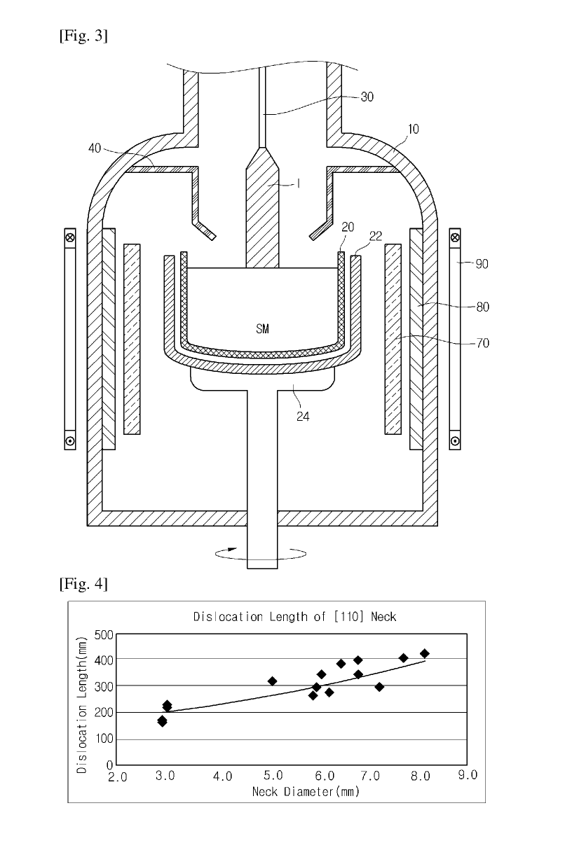

Hereinafter, an apparatus for manufacturing an ingot by using a method of growing an ingot according to an embodiment will be described. FIG. 3 is a cross-sectional view of an apparatus for manufacturing an ingot which is used for a method of growing an ingot according to an embodiment.

Referring to FIG. 3, an apparatus for growing a silicon monocrystalline ingot according to an embodiment may be an apparatus used in a CZ method of methods for manufacturing a silicon wafer.

An apparatus for growing a silicon monocrystalline ingot according to an embodiment includes a chamber 10, a first crucible 20 for containing a raw material, a cover part 100, a second crucible 22, a crucible rotation shaft 24, a lifting mechanism 30 for lifting an ingot, a heat shield 40 for blocking heat, and a resistance heater 70, an insulator 80, and a magnetic field generation device 90.

These detailed descriptions are as follows.

Referring to FIG. 3, the first crucible 20 may receive a raw material. The first crucible 20 may receive a polysilicon. Also, the first crucible 20 may receive a melting silicon in which the polysilicon is melted. The first crucible 20 may include quartz.

The second crucible may support the first crucible 20. The second crucible 22 may include graphite.

The first crucible 20 may be rotated in a clockwise or counterclockwise direction by the crucible rotation shaft 24. The lifting mechanism 30 to which a seed crystal is attached may be disposed above the first crucible 20 to lift the see crystal. The lifting mechanism 30 may be rotated in a direction opposite to the rotation direction of the crucible rotation shaft 24.

The seed crystal attached to the lifting mechanism 30 may be immersed into a silicon melt solution SM, and then the lifting mechanism 30 may be rotated to lift the seed crystal. As a result, a silicon monocrystalline may be grown to manufacture an ingot I.

Sequentially, the resistance heater 70 for applying heat into the first crucible 20 may be disposed adjacent to the second crucible 22. The insulator 80 may be disposed outside the resistance heater 70. The resistance heater 70 supplies heat for melting the polysilicon to produce the silicon melt solution SM. Also, during the manufacturing process, the resistance heater 70 may continuously supply heat into the silicon melt solution SM.

The silicon melt solution SM contained in the first crucible 20 may have a high temperature. Thus, heat may be released from an interface of the silicon melt solution SM. Here, if a large amount of heat is released, it may be difficult to maintain a proper temperature required for growing the silicon monocrystalline ingot. Thus, the heat released from the interface may be minimized, and also, it may prevent the heat from being transferred into an upper portion of the silicon monocrystalline ingot. For this, the heat shield 40 may be provided so that each of the silicon melt solution SM and the interface of the silicon melt solution SM are maintained at a high temperature.

The heat shield 40 may have various shapes so as to maintain thermal environments into a desired state to stably grow the crystal. For example, the heat shield 40 may have an empty cylindrical shape to surround the periphery of the silicon monocrystalline ingot. For example, the shield 40 may include graphite, graphite felt, or molybdenum.

The magnetic field generation device 90 which applies a magnetic field into the silicon melt solution SM to control convection current of the silicon melt solution SM may be disposed outside the chamber 10. The magnetic field generation device 90 may be a device which generates a magnetic field in a direction perpendicular to a crystal growth axis of the silicon monocrystalline ingot, i.e., a horizontal magnetic field (MF). In the current embodiment, the magnetic generation device 90 may acts from the process for melting the silicon. Particularly, the magnetic field generation device 90 may apply the magnetic field into a lower side of a surface of the silicon melt solution.

A particular feature, structure, or effects described in connection with the embodiment is included in at least one embodiment of the invention, and is not limited to only one embodiment. Further, when a particular feature, structure, or characteristic is described in connection with any embodiment, it is submitted that it is within the purview of one skilled in the art to effect such feature, structure, or characteristic in connection with other ones of the embodiments. Therefore, contents with respect to various variations and modifications will be construed as being included in the scope of the present disclosure.

### INDUSTRIAL APPLICABILITY

Since the apparatus and method for growing the ingot is available in the current embodiment, industrial applicability may be high.

What is claimed is:

1. A method of growing an ingot, the method comprising:
melting a silicon to prepare a silicon melt solution;
preparing a seed crystal having a crystal orientation [110];
growing a neck part from the seed crystal; and
growing an ingot having the crystal orientation [110] from the neck part, wherein the neck part has a diameter of about 4 mm to about 8 mm.

2. The method according to claim 1, wherein the silicon melt solution has a doping concentration of about 8.5×10¹⁸ atoms/cm³ to about 1.7×10¹⁹ atoms/cm³.

3. The method according to claim 2, wherein the silicon melt solution has a boron concentration of about 8.5×10¹⁸ atoms/cm³ to about 1.7×10¹⁹ atoms/cm³.

4. The method according to claim 1, wherein the seed crystal has a doping concentration of about 8.5×10¹⁸ atoms/cm³ to about 1.7×10¹⁹ atoms/cm³.

5. The method according to claim 4, wherein the seed crystal has a boron concentration of 8.5×10¹⁸ atoms/cm³ to about 1.7×10¹⁹ atoms/cm³.

6. The method according to claim 1, wherein the neck part has a length of about 400 mm or more.

7. The method according to claim 1, wherein, in the growing of the neck part, the neck part has a growth rate of about 3.0 mm/min to about 3.2 mm/min.

8. The method according to claim 1, wherein, in the growing of the ingot, the ingot has a lifting speed of about 0.9 mm/min or more.

9. The method according to claim 1, wherein, in the preparing of the silicon melt solution, a magnetic field is applied.

10. The method according to claim 9, wherein the magnetic field is applied into a lower side of a surface of the silicon melt solution.

11. The method according to claim 9, wherein the magnetic field has an intensity of about 1,500 G to about 3,500 G.

12. An ingot having the crystal orientation [110], the ingot being grown according to claims 1 to 11.
